(19) United States
(12) Patent Application Publication
(10) Pub. No.: US 2010/0308693 A1
(43) Pub. Date: Dec. 9, 2010

(54) Piezoelectric Stack Actuator Assembly

(76) Inventor: James R. Phillips, Albuquerque, NM (US)

Correspondence Address: Daniel J. Deneufbourg, Esq.;Senior Intellectual Property Counsel, CTS Corporation, 171 Covington Drive, Bloomingdale, IL, 60108, US

(21) Appl. No.: 12/788,416

(22) Filed: May 27, 2010

Related U.S. Application Data
(60) Provisional application No. 61/217,755, filed on Jun. 4, 2009.

(51) Int. Cl. H01L 41/083; H01L 41/047; H01L 41/053

(52) U.S. Cl. 310/340; 310/366

(57) ABSTRACT

A piezoelectric actuator assembly comprising at least a stack of interior piezoelectric wafers which, in one embodiment, each include first and second spaced-apart strips of conductive material defining first and second wrap-around electrodes. The interior wafers are stacked in an alternating relationship wherein the first electrodes and the second electrodes are disposed in an opposed relationship. In one embodiment, the assembly includes an end piezoelectric wafer located at each end of the stack of interior wafers and includes a wrap-around electrode in contact with the interior wafers. A conductive end plate is coupled to each of the end piezoelectric wafers. A terminal wire is coupled to each conductive end plate.

### CROSS-REFERENCE TO RELATED AND CO-PENDING APPLICATIONS

This application claims the benefit of the filing date of U.S. Provisional Patent Application Ser. No. 61/217,755 filed on Jun. 4, 2009 and entitled, “Piezoelectric Stack Actuator Assembly”, the entire disclosure of which is explicitly incorporated herein by reference as are all references cited therein.

### FIELD OF THE INVENTION

The present invention relates generally to piezoelectric substrates or wafers and, more particularly, to a piezoelectric stack actuator which is made of a plurality of individual piezoelectric wafers.

### BACKGROUND OF THE INVENTION

Piezoelectric devices find applications in a variety of products including ultrasonic transducers, hydrophones, motion control devices, vibration generation devices, inkjet printers, and actuators.

Low-temperature co-fired piezoelectric wafers or substrates have been used to make multilayer stack actuators using a method which initially involves casting a thin layer of PZT particles suspended in a binder matrix. An electrode pattern is then printed on a tape using thick film inks comprised of palladium, silver, or platinum. The tape layers are then aligned, stacked, pressed together, and co-fired to create the stack. The material, however, is costly and the method requires either vias to be punched into the tape layers and filled with conductive co-fire paste or wires to be soldered between the layers for connecting the electrodes. These types of connections, additionally, are subject to failure over time due to the constant expansion and contraction of the material. Another common failure is dielectric breakdown across the layers as a result of defects caused by variable layer thicknesses which may be created during the tape casting process.

Companies such as Physik Instrumente of Karlsruhe, Germany, produce multilayer piezoelectric stack actuators that are manufactured by using an epoxy layer between individual piezoelectric layers. The epoxy layer, however, creates a compliant intermediate layer that reduces the overall displacement of the stack. This epoxy layer based stack also requires separate wire leads to be attached to each layer which, in turn, often requires a tabbed metal shim to be placed between adjacent layers. These shims reduce the amount of piezoelectric material in the stack, thus disadvantageously reducing the amount of overall displacement of the stack.

The present invention is directed to a simpler, lower cost piezoelectric stack actuator assembly.

### SUMMARY OF THE INVENTION

The invention relates generally to a piezoelectric stack actuator assembly comprising at least a stack of first piezoelectric wafers each including first and second electrodes and the first piezoelectric wafers are stacked in an adjacent relationship wherein the first electrodes of the first piezoelectric wafers are in contact with each other and the second electrodes of the first piezoelectric wafers are in contact with each other and define respective first and second electrically conductive paths.

In one embodiment, the first and second electrodes of each of the first piezoelectric wafers are defined by first and second spaced-apart wrap-around strips of conductive material and each of the first piezoelectric wafers includes first and second window regions thereon devoid of any conductive material. In one embodiment, the first and second window regions are formed on the opposite front and back faces respectively of each of the first piezoelectric wafers.

In accordance with one embodiment of the invention, the first piezoelectric wafers are stacked in an adjacent, parallel relationship in which the first window regions, the second window regions, the first electrodes and the second electrodes of adjacent first piezoelectric wafers are disposed in an opposed relationship.

In one embodiment, the piezoelectric stack actuator assembly also comprises first and second end piezoelectric wafers each including at least a first strip of conductive material defining a first electrode. The first and second end piezoelectric wafers are stacked on opposite sides of the stack of first piezoelectric wafers respectively.

First and second conductive termination end plates may also be stacked on opposite sides of the end piezoelectric wafers respectively. An electrical termination wire is coupled to each of the terminator end plates.

In one embodiment, at least the first and end piezoelectric wafers are encapsulated in a layer of epoxy or sealant and then a layer of overmold material.

There are other advantages and features of this invention which will be more readily apparent from the following detailed description of preferred embodiments of the invention, the drawings, and the appended claims.

### BRIEF DESCRIPTION OF THE DRAWINGS

These and other features of the invention can best be understood by the following description of the accompanying drawings as follows:

FIG. 1 is an enlarged perspective view of a piezoelectric stack actuator assembly in accordance with the present invention;

FIG. 2 is an enlarged perspective view of the piezoelectric stack actuator assembly of FIG. 1 with the overmold material removed therefrom;

FIG. 3 is an enlarged side elevational view of the piezoelectric stack actuator assembly of FIG. 2 with the protective sleeve removed therefrom;

FIG. 4 is an enlarged side elevational view of one of the end plates of the piezoelectric stack actuator assembly of FIGS. 1-3;

FIG. 5 is a simplified enlarged and exploded side elevational view of the piezoelectric stack actuator assembly of FIGS. 1-3;

FIGS. 6A and 6B are respective enlarged side elevational views of the opposite front and back faces respectively of one of the interior piezoelectric wafers of the piezoelectric stack actuator assembly of the present invention; and

FIGS. 7A and 7B are respective enlarged side elevational views of the opposite front and back faces respectively of one of the two end piezoelectric wafers of the piezoelectric stack actuator assembly of the present invention.

### DETAILED DESCRIPTION OF THE EMBODIMENT

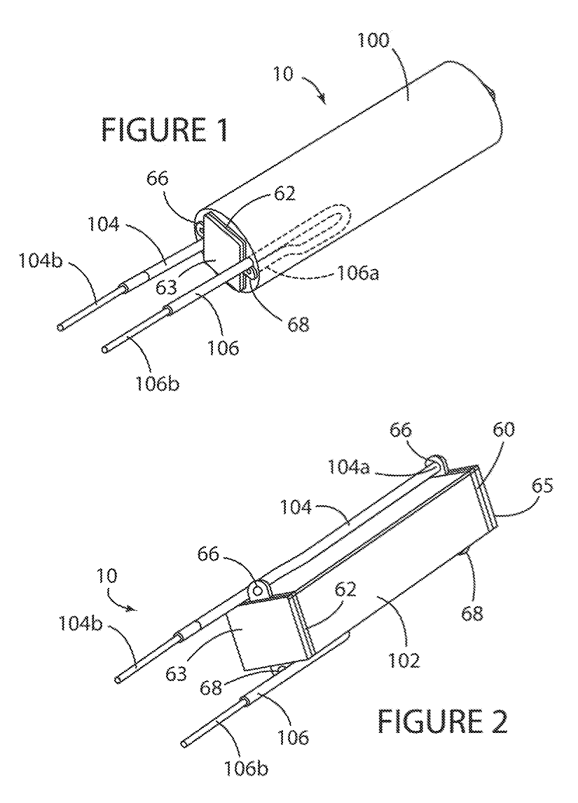

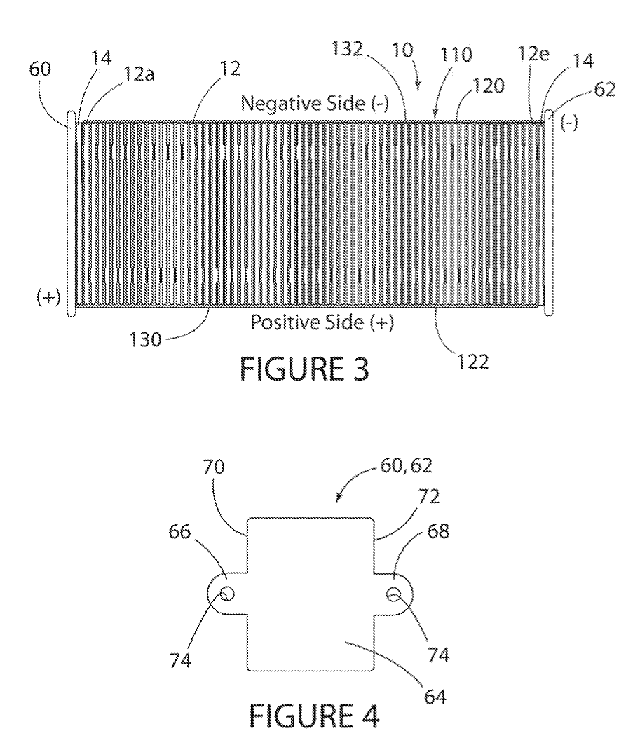

A complete piezoelectric stack actuator assembly 10 in accordance with the present invention is shown in FIG. 1. FIG. 2 shows the piezoelectric stack actuator assembly 10 of FIG. 1 without its exterior layer 100 of overmolded polymeric material. FIG. 3 shows the piezoelectric actuator assembly 10 of FIG. 2 without its outer protective sleeve or sealant layer 102 and terminal wires or leads 104 and 106.

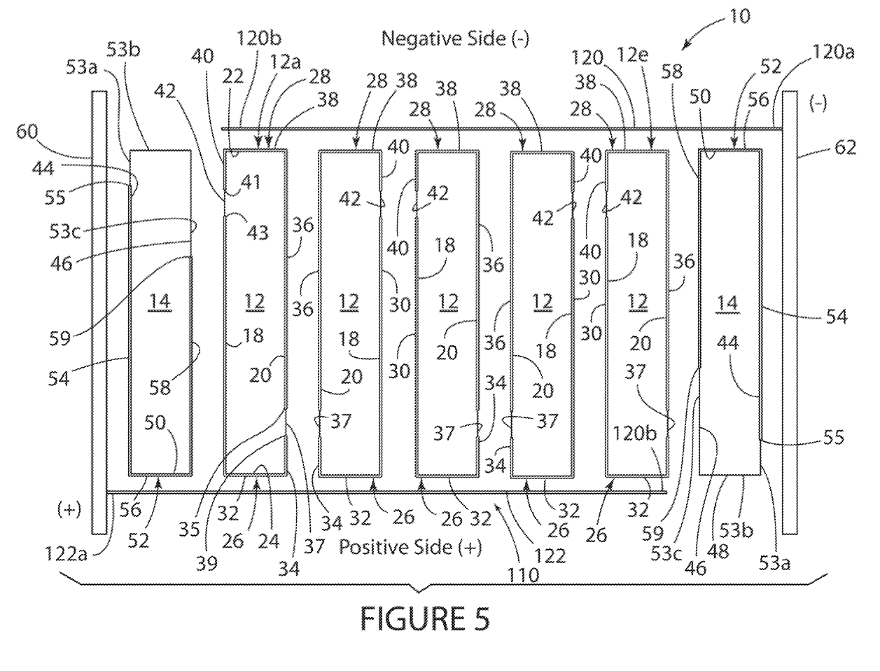

As shown in FIGS. 3 and 5, piezoelectric stack actuator assembly 10 comprises a stack or loaf 110 of piezoelectric wafers and, more specifically, a stack or loaf 110 including a plurality of first interior substrates or wafers or slices 12 of piezoelectric material and a pair of respective second or end or “dummy” substrates or wafers or slices 14 also of piezoelectric ceramic material which are coupled to the two outside interior wafers 12 and have all been stacked together in a “sliced bread loaf” type linear and abutting relationship as described in more detail below. FIG. 5 shows only five of the interior wafers 12 for illustration purposes.

Referring further to FIGS. 3, 5, 6A, 6B, 7A, and 7B, each of the interior and end piezoelectric wafers 12 and 14 of the stack 110 of the stack actuator assembly 10 is comprised of a solid, generally rectangularly-shaped block or slice 16 of piezoelectric ceramic material having uniform dimensions of about 0.360 inches in length by about 0.300 inches in width by about 0.005 inches in thickness. Each of the blocks or slices 16 may be made out of a wide variety of high density piezoelectric ceramic materials such as, for example, lead zirconate titanate (Pb(ZrTi)O₃), commonly known by the abbreviation PZT, or other suitable materials such as, for example, PMN-PT single crystal, quartz, or lithium niobate. The uniform dimensions and thickness of each of the blocks or slices 16 assure the generation and transmission of a uniform electric field across the entire stack 110 as described in more detail below. A typical length for the stack 110 is about 45 mm and includes about 500 individual wafers 12 and 14 stacked together.

Each of the respective interior and end piezoelectric wafers 12 and 14 additionally comprises one or more layers or strips of thin film conductive material which have been formed thereon as, for example, by standard sputtering techniques to form respective electrodes as described in more detail below.

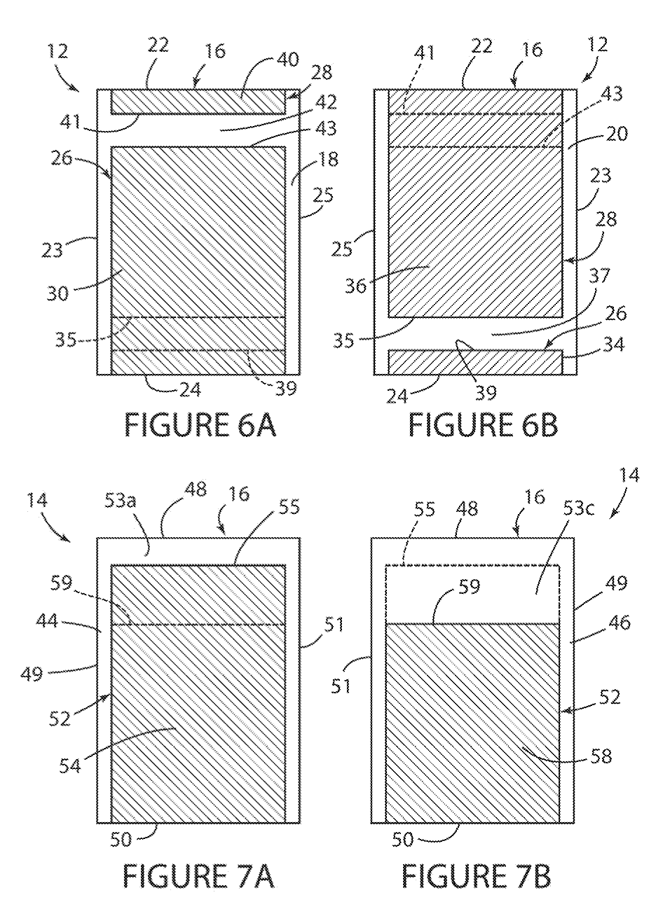

Specifically, and referring to FIGS. 5, 6A, and 6B, the block or slice 16 of piezoelectric ceramic material comprising each of the interior piezoelectric wafers 12 includes opposed exterior front and back faces 18 and 20, opposed exterior transverse end faces 22 and 24, and opposed exterior longitudinal side faces 23 and 25. First and second respective positive (+) and negative (−) polarity “wrap-around” electrodes 26 and 28, each comprising an elongate strip of a suitable thin film conductive material, such as nickel/vanadium alloy, nickel/chromium alloy, gold, aluminum, nickel, palladium, silver, palladium/silver alloy, or platinum, cover the exterior front and back faces 18 and 20 and wrap-around the exterior end faces 24 and 22 respectively.

The thickness of the thin film material defining the electrodes 26 and 28 is in the range of approximately 0.5 microns, as opposed to conventional thick film electrodes which have thicknesses in the range of 2 to 5 microns, to yield more active PZT material per unit length of the stack 110. The use of thin film material also eliminates the need for the intermediate glass layer which is formed at the electrode/PZT interface when thick film material is used, thus also eliminating parasitic capacitance and improving PZT performance.

Referring further to FIGS. 5, 6A, and 6B, electrode 26 on the block 16 of each of the interior wafers 12 includes a first portion 30 on the front face 18 of the block 16, a second “wrap-around” portion 32 (FIG. 5) extending unitarily from the first portion 30 which wraps around the end face 24 of the block 16, and an end portion 34 on the back face 20 of the block 16 which extends unitarily from the portion 32 and away from the end face 24 of the block 16.

Electrode 28, also on the block 16 of each of the interior wafers 12, includes a first portion 36 on the back face 20 of the block 16 which includes a transverse end peripheral edge 35 which is spaced from, and parallel to, the transverse end peripheral edge 39 of the end portion 34 of the electrode 26 to define a first generally rectangularly-shaped region or window 37 on the back face 20 of the block 16 which is devoid of conductive material (i.e., an area on the back face 20 of the block 16 with exposed PZT material). Electrode 28 further comprises a “wrap-around” portion 38 (FIG. 5) which extends unitarily from the first portion 36 and wraps around the end face 22 of the block 16, and an end portion 40 extending unitarily from the second portion 38 which terminates on the front face 18 of the block 16 in a relationship wherein a transverse end peripheral edge 41 thereof is spaced from, and parallel to, a transverse end peripheral edge 43 of the first portion 30 of electrode 26 on the front face 18 of the block to define a second generally rectangularly-shaped region or window 42 on the front face 18 of the block 16 which is devoid of conductive material (i.e., an area on the front face 18 of the block 16 of exposed PZT material).

Each of the longitudinally extending opposed elongate edges of each of the strip electrodes 26 and 28 is spaced from the respective opposed longitudinal elongate edges of the respective elongate side faces 23 and 25 of the block 16 which defines the wafer 12. In the embodiment shown, the window 37 is defined on the back face 20 of the block 16 adjacent and generally parallel to the transverse edge 24 of the block 16 while the window 42 is defined on the front face 18 of the block 16 adjacent and generally parallel to the opposed transverse edge 22 of the block 16.

FIGS. 3, 7A, and 7B depict each of the end piezoelectric wafers 14 and, more specifically, the block 16 thereof, which includes opposed exterior front and back faces 44 and 46; opposed exterior transverse end faces 48 and 50; and opposed longitudinal side faces 49 and 51. A “wrap-around” electrode 52 (defining either a positive or a negative electrode depending upon which end of the stack 110 the wafer 14 is placed) comprises an elongate strip of suitable conductive thin film material similar to the thin film material of the strips 26 and 28 and which covers the exterior front and back faces 44 and 46 of the block 16 and wraps around the end face 50 of the block 16 defining the wafer 14.

Referring further to FIGS. 3, 7A, and 7B, electrode 52 includes a first portion 54 extending on the front face 44 of the block 16 and defining a transverse end peripheral edge 55 spaced from and parallel to the end face 48 of the block 16; a wrap-around portion 56 (FIG. 5) which extends unitarily from the first portion 54 and wraps around the exterior of the end face 50 of the block 16; and a third portion 58 extending unitarily from the wrap-around portion 56 onto the back face 46 of the block 16 and defining a transverse end peripheral edge 59 which is spaced from and parallel to the end face 48 of the block 16. Each of the opposed longitudinal elongate edges of the strip electrode 52 is spaced from, and parallel to, each of the respective adjacent longitudinal edges of the respective side faces 49 and 51 of the block 16 defining the wafer 14.

In accordance with the embodiment of the wafer 14 shown in FIGS. 3, 7A, and 7B, the edge 59 of the electrode 52 is spaced a distance away from the edge 48 of the block 16 which is greater than the distance between the edge 55 of the electrode 52 and the edge 48 of the block 16 to define respective windows or regions 53a, 53b (FIGS. 5), and 53c on the block faces 44, 46, and 48 respectively which are devoid of conductive material (i.e., regions of exposed PZT material). Windows 53a and 53c are opposed to each other with window 53a being smaller in area than the window 53c.

As shown in FIGS. 3 and 5, the interior piezoelectric wafers 12 are positioned in the stack actuator assembly 10 in a parallel, side-by-side, abutting relationship (as shown in FIG. 3) in which the respective windows 37 of adjacent wafers 12 are disposed in an opposed, co-linear and aligned relationship; the respective windows 42 of adjacent wafers 12 are disposed in an opposed, co-linear and aligned relationship; the respective electrodes 26 of adjacent wafers 12 are disposed in an opposed and abutting relationship (as shown in FIG. 3); and the respective electrodes 28 of adjacent wafers 12 are disposed in an opposed and abutting relationship (as shown in FIG. 3).

The positioning and relationship of adjacent interior wafers 12 in a manner in which the respective windows 37 and the respective windows 42 oppose and are aligned with each other and the respective electrodes 26 and the respective electrodes 28 of adjacent wafers 12 oppose and are aligned with each other may be accomplished during the manufacturing process either by flipping every other interior wafer 12 from top to bottom or from side to side.

The stack actuator assembly 10 shown in FIG. 3 exemplifies and reflects the result of the manufacturing process in which alternating interior wafers 12 were flipped over from side-to-side to accomplish the desired placement between the windows 37 and windows 42 and the electrodes 26 and electrodes 28 into a relationship wherein all of the electrodes 26 of adjoining interior wafers 12 are located, coupled, and abutted together along a lower longitudinal edge or side or face 130 (FIG. 3) of the stack 110 to define a positive (+) polarity conductive path or side along the lower longitudinal edge 130 of the stack 110; and all of the electrodes 28 are located, coupled, and abutted together along the opposed and parallel upper longitudinal edge or side or face 132 (FIG. 3) of the stack 110 to define a negative (−) polarity conductive path or side along the upper longitudinal edge 132 of the stack 110.

The two end or “dummy” or termination wafers 14, which are coupled to the respective outside interior wafers 12 as described in more detail below, electrically couple and terminate the interior wafers 12 to respective positive (+) and negative (−) polarity conductive termination end plates or caps 60 and 62 which protect the wafers 12 and 14 and define the voltage supply and ground connection of the stack 110 of stack assembly 10.

Each of the end plates 60 and 62 (FIG. 4) includes a generally square-shaped flat plate member 64 and a pair of electrical brackets or tabs 66 and 68 protruding outwardly from opposed side edges 70 and 72 respectively in a co-linear relationship. Each of the brackets 66 and 68 defines a central through-hole 74.

As shown in FIGS. 1 and 2, the stack assembly 10 additionally comprises electrical insulator plates 63 and 65 coupled to the exterior surface of respective plates 62 and 60.

Referring back to FIG. 5, an end wafer 14 is coupled to each of the respective outside interior wafers 12, generally designated with the numerals 12a and 12e in FIGS. 3 and 5, in a relationship wherein: the face 46 of the block 16 defining each of the wafers 14 and, more specifically, the portion 58 of the electrode 52 on the face 46 of the block 16 of each of the wafers 14 is disposed generally opposite and parallel to and abutting (as shown in FIG. 3) the portion 30 of the electrode 26 on the face 18 of the outside interior wafer 12a (for the left side wafer 14) and the portion 36 of the electrode 28 on the face 20 of the outside interior wafer 12e (for the right side wafer 14); the window 53c on the face 46 of the block 16 is opposed to the window 42 of the wafer 12a (for the left side wafer 14) and the window 37 of the wafer 12e (for the right side wafer 14); and the portion 54 of the electrode 52 on the face 44 of the block 16 of each of the wafers 14 is disposed generally opposite and parallel to and abutting against (as shown in FIG. 3) the interior face of the rigid conductive end termination plate 60 (for the left side wafer 14) and the termination plate 62 (for the right side wafer 14).

Referring still further to FIGS. 3 and 5, it is understood that the negative electrode 28 of wafer 12e is coupled to and abuts the negative electrode 52 of the end wafer 14 which, in turn, is coupled to and abuts the interior surface of the negative end plate 62. In a like manner, the positive electrode 26 of the wafer 12a is coupled to and abuts the positive electrode 52 of the other end wafer 14 which, in turn, is coupled to and abuts the interior surface of the positive end plate 60.

As further shown in FIG. 5, the region of the end wafer 14 opposed to the terminal 26 on the wafer 12e is devoid of conductive material and assures the absence of any connection to the negative conductive path defined by the terminal 28 on the wafer 12e. In a like manner, the region of the end wafer 14 opposed to the terminal 28 on the wafer 12a is devoid of conductive material and assures the absence of any connection to the positive conductive path defined by the terminal 26 on the wafer 12a.

As shown in FIGS. 1 and 2, a single electrical termination wire or lead 104 includes one terminal end 104a (FIG. 2) coupled, as by welding or soldering or the like, to electrical connection tab 66 on the termination plate 60. The wire 104 extends the length of the stack 110 in a relationship abutting the outside face thereof and includes an opposed terminal end 104b (FIGS. 1 and 2) projecting outwardly away from the opposed termination plate 62 and adapted to be coupled to the negative (−) terminal (not shown) of a voltage supply source (not shown).

Another single electrical termination wire or lead 106 includes one terminal end 106a (FIG. 1) coupled to the electrical connection tab 68 (FIG. 1) on the termination plate 62 also as by welding or soldering or the like. The wire or lead 106 is located on the outside face of the stack 110 opposite the outside face thereof including the terminal wire 104 and includes an opposed terminal end 106b (FIGS. 1 and 2) which extends and protrudes outwardly from the plate 62 in a relationship opposed, spaced from, and parallel to, the end 104b of the terminal wire 104. The terminal end 106b is adapted for coupling to the positive terminal (not shown) of a voltage supply source (not shown).

As shown in FIGS. 3 and 5, respective layers 120 and 122 of conductive paint can be applied to the respective positive and negative bottom and top longitudinal edges or sides 132 and 130 of the stack 110 and, more specifically, can be applied to the respective regions 38 and 32 of the respective positive and negative terminals 28 and 26 of the stack 110 to improve stack performance as well as to reduce resistivity between the wafers 12 and 14.

As shown in FIG. 5, a first end 120a of the layer 120 is abutted against the interior surface of the termination plate 62 and covers the region 56 of the terminal 52 of the end wafer 14 adjacent the wafer 12e while an opposed second end 120b of the layer 120 does not extend over or cover the end wafer 14 adjacent the wafer 12a and is spaced from the termination plate 60. In a like manner, a first end 122a of the layer 122 extends over and covers the region 56 of the terminal 52 on the end wafer 14 adjacent the wafer 12a and is abutted against the interior surface of the termination plate 60 while an opposed second end 122b of the layer 122 does not extend over or cover the opposed end wafer 14 adjacent the wafer 12e and is spaced from the termination plate 62.

As shown in FIG. 2, all four of the exterior sides or faces of the stack 110, including the electrical termination wires 104 and 106, are covered with a layer of protective epoxy or sealant 102 and then, as shown in FIG. 1, the stack 110 is overmolded with a layer of polymeric material 100. The protective sealant layer 102 prevents any of the overmold material 100 from ingressing or penetrating into and between the wafers 12 and 14.

Piezoelectric materials can become piezoelectric by a process called poling. This process can only be carried out at temperatures below the Curie point, when the crystal structures cause an electric dipole to be created. In perovskite structures, the dipole is created by movement of the central ion in the structure (usually a large metal ion). Below the Curie temperature, the central ion moves out of the plane of the structural ions and so the charges no longer balance and give a dipole.

The process of poling involves aligning the individual dipole moments, so that they all point in the same general direction. This is accomplished by putting the crystal in a constant electric field to force the dipoles to align. In the electric field, each dipole will feel a torque if it is not parallel to the field lines produced, and so is turned to that direction. When the electric field is removed, the dipoles remain aligned.

If a drive voltage is applied in the same direction as the poling voltage, each piezoelectric wafer 12 and 14 will expand in thickness according to the formula:

Δt=d33*Vdrive

The total expansion of the stack 110 of actuator assembly 10 is then equal to the individual wafer Δt times the number of piezoelectric wafers 12 and 14 in the stack. The blocked force of the stack actuator assembly 10 is:

Force=(Vdrive*A)/(g33*t)

where A is the active area of each of the piezoelectric wafers 12.

In accordance with the present invention, an odd number of wafers 12 and 14 must be used to avoid the “even number” stack configuration which will result in a shorted electrical path.

A poling electric field of approximately 50,000 volts/inch can be applied to conductive end plates 60 and 62 via the respective termination wires 104 and 106, and then across the individual wafers 12 of piezoelectric stack actuator assembly 10 via the abutting respective positive and negative terminals 26 and 28, to pole the piezoelectric wafers 12.

An alternate means of poling piezoelectric wafers 12 involves applying a poling electric field of approximately 50,000 volts/inch across the conductive electrodes 26 and 28 of individual piezoelectric substrates 12 prior to assembly into the stack 10.

Moreover, and although not described in great detail below, it is understood that the stack 110 of assembly 10 is required to be placed in a preload condition in which the piezoelectric wafers 12, wafers 14, and end plates 60 and 62 are compressed together into a coupling, contacting relationship in which the opposed electrodes 26 and opposed electrodes 28 of adjacent interior wafers 12 and the electrode 52 of wafers 14 are positioned in an abutting contacting relationship. In accordance with the present invention, the stack 110 of assembly 10 can be placed in a separate preload housing which compresses the wafers 12, wafers 14, and end plates 60 and 62 together into their preload configuration; or, alternatively, the stack 110 of assembly 10 can be coated or encapsulated in the layer of epoxy 102 and heat shrink tubing following compression of the wafers 12, wafers 14, and plates 60 and 62 against each other during the assembly process.

The stack assembly 10 shown and described herein and, more specifically, the individual piezoelectric wafers 12 and 14 thereof with respective electrodes 26, 28 and 52 formed and positioned thereon as described in detail above, advantageously allows an actuator assembly 10 composed of individual wafers to be stacked and interconnected together without the need for interconnection wires coupled to each of the wafers thus creating a simpler, less costly structure.

While the invention has been taught with specific reference to the embodiment shown herein, someone skilled in the art will recognize that changes can be made in form and detail without departing from the spirit and the scope of the invention. The described embodiment is to be considered in all respects only as illustrative and not restrictive. The scope of the invention is, therefore, indicated by the appended claims rather than by the foregoing description. All changes that come within the meaning and range of equivalency of the claims are to be embraced within their scope including, for example, an embodiment in which the overmolded layer 100 defines respective channels for the termination wires 104 and 106 and an embodiment in which the respective first and second wrap-around strip electrodes of the wafers 12 have been substituted with respective first and second conductive vias extending through the block 16 thereof and the wrap-around electrode of the wafers 14 has been substituted with a conductive via extending through the block 16 thereof.

What is claimed is:

1. A piezoelectric stack actuator assembly comprising at least a stack of interior piezoelectric wafers each including at least first and second spaced-apart strips of conductive material defining first and second electrodes and first and second window regions thereon devoid of any conductive material, the interior piezoelectric wafers being stacked in an adjacent, parallel relationship wherein the first window regions, the second window regions, the first electrodes, and the second electrodes thereof are respectively disposed in an opposed relationship.

2. The piezoelectric stack actuator assembly of claim 1 further comprising first and second end piezoelectric wafers each including at least a first strip of conductive material defining a first electrode, the first and second end piezoelectric wafers being stacked on opposite sides of the stack of interior piezoelectric wafers.

3. The piezoelectric stack actuator assembly of claim 2 further comprising first and second conductive plates stacked on opposite sides of the end piezoelectric wafers respectively.

4. The piezoelectric stack actuator assembly of claim 3 further comprising first and second layers of conductive paint applied to the first and second electrodes respectively.

5. The piezoelectric stack actuator assembly of claim 3 wherein the stack of piezoelectric wafers is encapsulated in a layer of epoxy.

6. The piezoelectric stack actuator assembly of claim 5, wherein a layer of polymeric material surrounds the layer of epoxy.

7. The piezoelectric stack actuator assembly of claim 1, wherein each of the interior piezoelectric wafers includes opposed front and back faces and opposed transverse top and bottom edges, the first and second window regions being defined on the opposed front and back faces of each of the interior piezoelectric wafers respectively adjacent the transverse top and bottom edges respectively and the first and second electrodes wrap around the transverse top and bottom edges respectively.

8. A piezoelectric stack actuator assembly comprising at least a stack of first piezoelectric wafers each including first and second electrodes, the first piezoelectric wafers being stacked in an adjacent relationship wherein the first electrodes of the first piezoelectric wafers contact each other and the second electrodes of the first piezoelectric wafers contact each other and define respective first and second electrically conductive paths along the stack.

9. The piezoelectric stack actuator assembly of claim 8 further comprising an end piezoelectric wafer coupled to the one of the first piezoelectric wafers at each end of the stack of first piezoelectric wafers, the end piezoelectric wafer defining a first electrode in coupling relationship with the first or second electrode of the one of the first piezoelectric wafers at each end of the stack.

10. The piezoelectric stack actuator assembly of claim 8 wherein the first and second electrodes on each of the first piezoelectric wafers are defined by respective spaced-apart first and second strips of conductive material wrapping around the first and second edges of the first piezoelectric wafers, and the first electrode on the end piezoelectric wafer is defined by a strip of conductive material wrapping around one of the opposed edges thereof.

11. The piezoelectric actuator assembly of claim 9 further comprising an end termination plate coupled to each of the end piezoelectric wafers and a termination wire coupled to each of the end termination plates.

12. A piezoelectric stack actuator assembly comprising:
a stack of first piezoelectric wafers each including a first electrode along a first edge thereof and a second electrode along an opposed second edge thereof, the first electrodes of the first piezoelectric wafers being in contact with each other to define a first conductive path along a first edge of the stack and the second electrodes of the first piezoelectric wafers being in contact with each other to define a second conductive path along a second edge of the stack;
an end piezoelectric wafer coupled to each end of the stack of first piezoelectric wafers, the end wafer including a first electrode along a first edge thereof in contact with the first or second electrode of the first piezoelectric wafers;
a termination plate coupled to each of the end piezoelectric wafers; and
a termination wire coupled to each of the termination plates.

13. The piezoelectric stack actuator assembly of claim 12 further comprising a layer of conductive paint extending over the first and second electrodes of the first piezoelectric wafers and the first electrode of the end piezoelectric wafer.

14. The piezoelectric stack actuator assembly of claim 12 further comprising:
a sealant layer surrounding the stack; and
a layer of overmold material surrounding the sealant layer.
